(19) United States
(12) Patent Application Publication
(10) Pub. No.: US 2026/0110810 A1
(43) Pub. Date: Apr. 23, 2026

(54) FLEXIBLE RADIATION DETECTORS

(71) Applicant: VAREX IMAGING CORPORATION, Salt Lake City, UT (US)

(72) Inventors: Marcelo C. Costa, Draper, UT (US); Carlo Tognina, Salt Lake City, UT (US)

(21) Appl. No.: 19/295,325

(22) Filed: Aug. 8, 2025

Related U.S. Application Data
(60) Provisional application No. 63/711,066, filed on Oct. 23, 2024.

(51) Int. Cl. G01T 1/24; H05K 1/02; H05K 1/18

(52) U.S. Cl. CPC G01T 1/244; H05K 1/028; H05K 1/189; H05K 2201/10151

(57) ABSTRACT

Radiation detectors including flexible components, such as flexible electronics boards and flexible covers, are disclosed. A radiation detector can include a flexible housing, an electronics board positioned in the flexible housing, and a sensor array at least partially overlapping the electronics board. The electronics board can include at least two rigid portions and a flexible portion coupled to the rigid portions. Each of the rigid portions can include active components.

### CROSS-REFERENCE TO RELATED APPLICATION(S)

This application claims priority to U.S. Provisional Application No. 63/711,066, filed 23 Oct. 2024, the entire disclosure of which is hereby incorporated by reference.

### FIELD

The described embodiments relate generally to radiation detectors (e.g., x-ray detectors), and more particularly, to radiation detectors including flexible components that allow the radiation detectors to bend and flex.

### BACKGROUND

Radiation detectors can be used to generate two-dimensional images or video in response to incident radiation. Radiation detectors can be used in a variety of contexts, including medical and industrial imaging. In some contexts, forces can be applied to a radiation detector, which can cause the radiation detector to bend or flex and can damage components of the radiation detector. In other contexts, a radiation detector can be wrapped around an object to be imaged, in which case usability of the radiation detector can be improved by allowing the radiation detector to bend or flex. As a result, it can be desirable to provide radiation detectors that can bend and flex without components thereof being damaged.

### SUMMARY

In one aspect, a radiation detector can include a flexible housing, an electronics board positioned in the flexible housing, and a sensor array at least partially overlapping the electronics board. The electronics board can include at least two rigid portions and a flexible portion coupled to the rigid portions. Each of the rigid portions can include active components.

In some examples, the radiation detector can further include a flexible cover. The flexible cover can include a polymer.

In some examples, the radiation detector can further include a baseplate. The baseplate can include one or more materials selected from carbon fiber, plastic materials, metal materials, fiberglass, or an epoxy resin. The baseplate can be configured to provide the flexible housing with a desired level of stiffness. In some examples, the flexible housing can include a plastic material.

In some examples, the radiation detector can further include a second flexible portion. The first flexible portion can extend in a first direction and the second flexible portion can extend in a second direction perpendicular to the first portion. The flexible portion can be defined by a flexible layer extending between the at least two rigid portions.

In another aspect, a radiation detector can include a first integrated circuit; a second integrated circuit coupled to the first integrated circuit by a flexible connection; a housing enclosing the first integrated circuit, the second integrated circuit, and the flexible connection; and a sensor array coupled to the first integrated circuit.

In some examples, the sensor array can be disposed within the housing. In some examples, the sensor array can at least partially overlap at least one of the first integrated circuit, the second integrated circuit, or the flexible connection. In some examples, the sensor array can be disposed outside of the housing.

In some examples, the first integrated circuit can be formed on a first rigid portion of an electronics board and the second integrated circuit can be formed on a second rigid portion of the electronics board. The flexible connection can be a flexible portion of the electronics board extending between the first and second rigid portions.

In some examples, the radiation detector can further include a cover coupled to the housing. The cover and the housing can define an enclosure in which the first integrated circuit and the second integrated circuit are disposed. In some examples, the cover can include polyethylene terephthalate or polyimide.

In yet another aspect, an imaging system includes an x-ray source and an x-ray detector. The x-ray detector can include an electronics housing including an electronics board and a sensor array coupled to the electronics housing. The electronics board can include a flex between two rigid portions. The rigid portions can include active components. The sensor array can include a plurality of sensors disposed outside of a periphery of the electronics housing.

In some examples, the flex can be a first flex extending in a first direction. The electronics board can further include a second flex. The second flex can extend in a second direction parallel to the first direction.

In some examples, the flex can be a first flex extending in a first direction. The electronics board can further include a second flex. The second flex can extend in a second direction perpendicular to the first direction.

In some examples, the electronics housing can include a flexible cover coupled to a flexible housing portion. The flexible housing portion can define a back surface and sidewalls of the electronics housing. In some examples, the sensor array can be a flexible sensor array configured to be wrapped around an object to be imaged.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A is a top view block diagram of a radiation detector.

FIG. 1B is a side view block diagram of the radiation detector of FIG. 1A.

FIG. 2 is a top view block diagram of a radiation detector.

FIG. 3A is a top view block diagram of an electronics board.

FIG. 3B is a top view block diagram of an electronics board.

FIG. 3C is a top view block diagram of an electronics board.

FIG. 4 is a block diagram of a radiation imaging system.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to radiation detectors that can be used to detect radiation, such as x-rays. Radiation detectors can be used for imaging in a variety of contexts, including medical imaging, diagnostics, radiotherapy, non-destructive testing, materials detection or analysis, security inspection, and the like. The following disclosure relates to radiation detectors with improved flexibility. The radiation detectors can achieve a variety of improvements, including improved durability and longevity, reduced weight, and reduced cost.

A radiation detector can include an electronics board disposed in a housing. Conventionally, the electronics board is a rigid component that can be susceptible to damage as a result of flexing or bending of the housing. Damaging the electronics board can render the radiation detector inoperable. As a result, conventional radiation detectors are designed to be rigid in order to protect the electronics board. This can include a rigid housing, components positioned within the housing to increase the rigidity of the radiation detector, and a glass cover. Common failures for radiation detectors can include the glass cover breaking, damage to the electronics board, and damage to the connection between the electronics board and the glass cover.

Radiation detectors of the present disclosure can include components that provide desired levels of flexibility and stiffness. For example, a radiation detector can include a flexible electronics board. In some examples, the flexible electronics board can include rigid portions with active components provided therein, and flexible portions with electrical connections between the active components. A majority of the flexible electronics board can include the rigid portions, or the flexible portions. In some examples, active components of the flexible electronics board can be electrically coupled to the flexible portion, and areas in which the active components are coupled can optionally include layers, materials, or components to stiffen or increase the rigidity of those areas. In some examples, a cover of the radiation detector can be formed from a flexible material, such as a polymer material. In some examples, a housing of the radiation detector can be formed from a flexible material, such as a polymer material, a plastic material, or another flexible material. Various combinations of the flexible electronics board, the flexible cover, and the flexible housing can be included in a radiation detector in order to decrease cost and weight; increase a design freedom, longevity, and durability; and improve usability of the radiation detector.

Throughout the present disclosure, materials that are described as being flexible can have a Young's modulus in a range from about 1 GPa to about 10 GPa, from about 0.5 GPa to about 5 GPa, or the like and a yield strength in a range from about 5 MPa to about 150 MPa, from about 10 MPa to about 100 MPa, or the like. By utilizing flexible materials in radiation detectors (e.g., as a housing, cover, as part of an electronics board, etc.), the radiation detectors can have increased survivability (e.g., in cases of a drop event, a large force being applied, or the like). For example, the radiation detectors can allow for bending or flexing in a drop event, an event in which the radiation detectors are used as a lever, or the like, and can return to their original shape without components thereof breaking or being damaged. This increases the longevity of the radiation detectors and allows for radiation detectors to be used in a broader range of contexts.

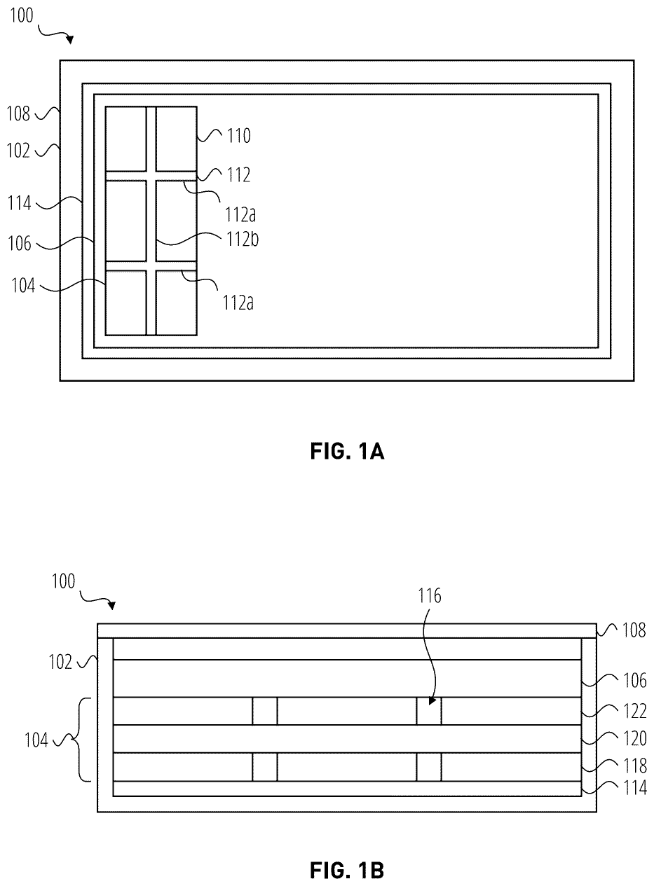

These and other examples are discussed below with reference to FIGS. 1A through 4. However, those skilled in the art will readily appreciate that the detailed description given herein with respect to these figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIGS. 1A and 1B illustrate a top view and a side view block diagram, respectively, of a radiation detector 100. The radiation detector 100 can be used to detect radiation, and can be used in a variety of contexts, including medical imaging, diagnostics, radiotherapy, non-destructive testing, materials detection or analysis, security inspection, and the like. The radiation detector 100 is a device configured to acquire data in response to incident radiation (e.g., x-rays or the like). The data can include image data, video data, or the like. The radiation detector 100 can include a housing 102, an electronics board 104, a sensor array 106, and a cover 108. The housing 102 and the cover 108 can define an internal volume in which the electronics board 104 and the sensor array 106 can be disposed and mounted. As will be discussed in detail, the housing 102, the electronics board 104, and the cover 108 can be formed at least partially from flexible materials such that the radiation detector 100 is a flexible radiation detector.

The housing 102 can be configured to support various components of the radiation detector 100, such as the electronics board 104, the sensor array 106, the cover 108, antennas, batteries, or the like. The housing 102 can be formed from materials having an ability to flex and return to their original shape. The design of the housing 102 can intentionally allow for flexing. For example, the housing 102 can omit various internal structural features, such as ribs, depressions, grooves, posts, or the like that would otherwise provide a rigid or semi-rigid housing. The housing 102 can be formed from various materials having a desired level of stiffness, flexibility, and elasticity, while having a minimal density. For example, the housing 102 can be formed from a plastic material, a polymer material, or the like. The housing 102 can include internal structural features such as ribs, depressions, grooves, posts, or the like to provide a desired level of support or rigidity to the housing 102. By forming the housing 102 from a flexible material, the radiation detector 100 can have an increased durability and longevity.

The sensor array 106 is configured to generate an image in response to incident radiation. The sensor array 106 is positioned in, and can be coupled to, the housing 102. The sensor array 106 can include a variety of sensors configured to generate data based on incident radiation. The sensor array 106 can include direct conversion sensors, indirect conversion sensors, photon counters, radiation conversion materials (e.g., scintillator materials), or the like.

The electronics board 104 is disposed in the housing 102 and coupled to the sensor array 106. The electronics board 104 is configured to control the sensor array 106, processing of image data from the sensor array 106, transmission of that data from the radiation detector 100, and other operations of the radiation detector 100. The electronics board 104 can include control logic for the radiation detector 100. The electronics board 104 can include a general-purpose processor, a digital signal processor (DSP), an application specific integrated circuit (ASIC), a microcontroller, a programmable logic device (e.g., a field programmable gate array (FPGA) or the like), discrete circuits, a combination of such devices, or the like. In addition, other interface devices, such as circuit chipsets, hubs, memory control logics, communication interfaces, or the like may be part of or coupled with the electronics board 104 to connect the electronics board 104 to internal and external components of the radiation detector 100. The electronics board 104 can include active components or circuits, such as integrated circuit (IC) chips, which can include ASICs, FPGAs, system-on-chips (SoCs), readout circuits, amplifiers, analog to digital converters, processors, or the like. In some examples, the electronics board 104 can include an ASIC, a processor, and a programmable logic device, which can each be coupled to a memory. The active components can be configured to perform various operations on data received from the sensor array 106, configured to control the sensor array 106, configured to control other functions of the radiation detector 100, or the like

As illustrated in FIGS. 1A and 1B, the electronics board 104 can include rigid portions 110 and flexible portions 112. Active components of the electronics board 104 can be disposed within the rigid portions 110. The active components can be formed in the rigid portions 110 or coupled to the electronics board 104 within the rigid portions 110. The active components from different rigid portions 110 can be coupled to each other through the flexible portions 112. As an example, an ASIC can be provided in a first rigid portion 110, an FPGA can be provided in a second rigid portion 110, and the ASIC can be coupled to the FPGA through connections that extend through the flexible portions 112.

FIG. 1B illustrates a configuration for providing the rigid portions 110 and the flexible portions 112. As illustrated in FIG. 1B, the electronics board 104 can include a first rigid layer 118, a flexible connection layer 120, and a second rigid layer 122 in a stacked configuration. The first and second rigid layers 118, 122 can be present in the rigid portions 110 and can be removed from the flexible portions 112. For example, openings 116 can be etched through the first and second rigid layers 118, 122 in the flexible portions 112 to expose the connection layer 120. This arrangement allows for active components to be formed in the first and second rigid layers 118, 122 while the openings 116 allow the electronics board 104 to move (e.g., bend or flex) in the flexible portions 112.

Each of the layers 118, 120, 122 can include one or more layers of conductive materials and/or one or more layers of conductive materials. The first and second rigid layers 118, 122 can include a rigid substrate, such as an FR-4 glass epoxy, another glass-reinforced epoxy laminate material, or the like. Active components of the electronics board 104 can be formed on, in, or coupled to the first and second rigid layers 118, 122. By forming the active components of the electronics board 104 in the rigid portions 110, connections to the active components (e.g., solder joints or the like) can be protected from damage that can occur when the connections move or bend. The connection layer 120 can include conductive traces, which can interconnect the active components of the first and second rigid layers 118, 122. As illustrated in FIG. 1B, the connection layer 120 can extend across the electronics board 104 and can provide electrical connections between active components in portions of the first and second rigid layers 118, 122 that are separated from one another by the openings 116. Thus, the electronics board 104 can provide active components in the rigid portions 110 and the active components can be coupled to one another through the flexible portions 112.

Although FIG. 1B illustrates the connection layer 120 as being disposed between the first rigid layer 118 and the second rigid layer 122, the electronics board 104 can have any suitable arrangement with any number of rigid and flexible layers. For example, the electronics board 104 can include a single rigid layer and a single flexible connection layer; a single rigid layer with flexible connection layers on opposite sides of the rigid layer; or any greater number of layers stacked in order to provide active components and connections therebetween. Further, FIG. 1B illustrates the electronics board 104 as including a laminated structure. In some examples, the connection layer 120 can be replaced by wires, a ribbon cable, any other flexible connectors, or any other flexible connections that can be coupled between the rigid portions 110.

In the example illustrated in FIGS. 1A and 1B, the electronics board 104 includes two horizontal flexes 112a (extending in a direction perpendicular to a longitudinal axis of the electronics board 104) and a single vertical flex 112b (extending in a direction parallel to the longitudinal axis of the electronics board 104). The number and arrangement of the horizontal flexes 112a and the vertical flexes 112b can provide the electronics board 104 with varying degrees of flexibility in directions parallel to the horizontal flexes 112a and the vertical flexes 112b. Providing a greater number of flexible portions 112 or providing the flexible portions 112 with greater widths can provide the electronics board 104 with greater levels of flexibility in directions parallel to the respective flexible portions 112. The layout of the rigid portions 110, the horizontal flexes 112a, and the vertical flexes 112b can enable the electronics board 104 to bend to specific radii or shapes. The horizontal flexes 112a and the vertical flexes 112b can have widths in a range from about 1 mm to about 20 mm, in a range from about 1 mm to about 5 mm, or the like. The flexible portions 112 can define an area of the electronics board 104 in a range from about 10% to about 40%, from about 10% to about 30%, from about 15% to about 25%, or the like. The flexible portions 112 can have any suitable arrangements, and flexible portions 112 can be provided in diagonal directions, can be provided with curves, or the like. Providing greater areas of the flexible portions 112 can leave less space for active components in the rigid portions 110, and the arrangement of the flexible portions 112 and the rigid portions 110 can be optimized for applications of the radiation detector 100.

The arrangement of the flexible portions 112 can be dependent on the flexibility of the radiation detector 100 (e.g., the housing 102, the cover 108, and the like) and any flexing likely to be experienced by the radiation detector 100 and the electronics board 104. If the radiation detector 100 is likely to be used as a lever and flex or bend in a direction perpendicular to a longitudinal axis of the radiation detector, a greater number of horizontal flexes 112a can be provided to account for this likely bending or flexing. The flexible portions 112 can be distributed across the electronics boards 104 in areas that are most likely to experience bending or flexing (e.g., in central areas), near areas that are most likely to render the radiation detector 100 inoperable as a result of flexing or bending, or the like. As such, the flexible portions 112 can be included in the electronics board 104 to allow the electronics board 104 to bend or flex with the radiation detector 100 and increase the survivability of the radiation detector 100, the longevity of the radiation detector 100, and the like.

In some examples, the housing 102 can include a baseplate 114. The baseplate 114 can be provided to increase a stiffness or rigidity of the housing 102. The baseplate 114 can be formed from materials having a desired level of stiffness, flexibility, and elasticity, while having a minimal density. For example, the baseplate 114 can be formed from metals, such as aluminum or steel; carbon fiber; plastic materials; polymer materials; fiberglass; an epoxy resin; or the like. The baseplate 114 can be mounted to the housing 102 by any suitable means, such as brazing, fasteners, clips, glues, threads, welding, soldering, or the like. The baseplate 114 can be a plate, a bar, a beam, a rod, combinations or multiples thereof, or the like. The baseplate 114 can extend across any suitable area of the radiation detector 100 depending on the stiffness, rigidity, flexibility, weight, and other characteristics to be achieved by the baseplate 114. The baseplate 114 can extend completely or partially across an area between opposite sidewalls of the housing 102. The baseplate 114 can be a solid plate, a grid, a lattice, or any other suitable configuration for providing a desired level of stiffness, rigidity, flexibility, weight, and the like to the radiation detector 100.

In conventional radiation detectors, foam, rubber, plastic materials or the like can be included within a housing in order to add stiffness to the radiation detector and protect components of the radiation detector. Because the radiation detector 100 includes flexible components that are less prone to damage caused by flexing, bending, or the like, these stiffening materials can be omitted from the radiation detector 100. This can reduce the size, cost, and weight of the radiation detector 100 and increase freedom of design for the radiation detector 100. In some examples, the configuration of the radiation detector 100 of FIGS. 1A and 1B can reduce a weight of the radiation detector 100 by at least about 10% relative to a conventional radiation detector of a similar size and fidelity.

As illustrated in FIGS. 1A and 1B, in some examples, the cover 108, the sensor array 106, the electronics board 104, the baseplate 114, and the housing 102 can overlap one another. Specifically, the electronics board 104 can be disposed in the same footprint or within a periphery of each of the cover 108, the sensor array 106, the baseplate 114, and the housing 102. Each of the components of the radiation detector 100 can be flexible, and the entire radiation detector 100 can be configured to flex or bend without breaking or damaging the components thereof. In some examples, at least some of the components of a radiation detector can be disposed side-by-side or can otherwise not overlap one another. The electronics board 104, the sensor array 106, and the baseplate 114 can be disposed within an enclosure defined by the housing 102 and the cover 108. The baseplate 114, the electronics board 104, and the sensor array 106 can have a stacked configuration, as illustrated in FIG. 1B. Additional components, such as antennas, batteries, and the like can also be disposed within the enclosure defined by the housing 102 and the cover 108. Positioning the sensor array 106 adjacent or proximal to the cover 108 can limit attenuation of incident x-rays by structures of the radiation detector 100.

The cover 108 can be connected or coupled to the housing 102. The cover 108 and the housing 102 can form an enclosure surrounding the sensor array 106. In some examples, the enclosure can be completely sealed once the cover 108 is attached to the housing 102. In some examples, other structures, such as screws with seals, electrical connectors or contacts, over-center cams, plastic hinges, cantilever snaps, hinge and pin connections, pressure sensitive adhesive, or the like can be included to seal the enclosure. The cover 108 can be formed from flexible materials, which can be the same as or similar to materials used to form the housing 102. The cover 108 can be formed from a plastic material, a polymer material, or the like, such as polyethylene terephthalate (PET), polyimide, or the like. By forming the cover 108 from a flexible material, the radiation detector 100 can have an increased durability and longevity. By forming both the cover 108 and the electronics board 104 from flexible materials, failures in the radiation detector 100 caused by damage to a cover glass, an electronics board, and a connection between the cover glass and the electronics board (e.g., three of the top causes of failure for the radiation detector 100) can be reduced or eliminated. This can significantly reduce failures in the radiation detector 100.

The housing 102 and the cover 108 can be formed from flexible materials, such as materials having a Young's modulus in a range from about 1 GPa to about 10 GPa, from about 0.5 GPa to about 5 GPa, or the like and a yield strength in a range from about 5 MPa to about 150 MPa, from about 10 MPa to about 100 MPa, or the like. By utilizing flexible materials in the housing 102 and the cover 108, the radiation detector 100 can have an increased survivability (e.g., in cases of a drop event, a large force being applied, or the like). For example, the radiation detector 100 can allow for bending or flexing in a drop event, an event in which the radiation detector 100 is used as a lever, or the like, and can return to its original shape without components thereof breaking or being damaged. This increases the longevity of the radiation detector 100 and allows for the radiation detector 100 to be used in a broader range of contexts.

Some use cases of the radiation detector 100 can benefit from the radiation detector 100 having at least a minimal level of stiffness or rigidity. For example, in a medical context, the radiation detector 100 can be used to image a patient on a bed. The radiation detector 100 can be used as a lever to move the patient in order to position the radiation detector 100 in a desired position relative to the patient. By providing the housing 102 with a desired degree of stiffness or rigidity (such as by including the baseplate 114), the housing 102 can function as a lever and enable a broad range of use cases. By including flexible components in the radiation detector 100 (e.g., the housing 102, the electronics board 104, and the cover 108), the radiation detector 100 can remain operable, even if the radiation detector 100 bends or flexes when being used as a lever.

In another use case, the radiation detector 100 can be wrapped around a pipe or other object for imaging the object. In such cases, adding flexibility to the radiation detector 100 can help with positioning the detector relative to the object, while avoiding damage to the components of the radiation detector 100.

Accordingly, the radiation detector 100 of FIGS. 1A and 1B can tolerate greater flexing while still remaining operable after the flexing. The radiation detector 100 can include minimal stiffening and other components to increase the rigidity of the radiation detector 100, and can have a reduced size (e.g., thickness), weight, and cost. The radiation detector 100 can have increased design flexibility, durability, and longevity.

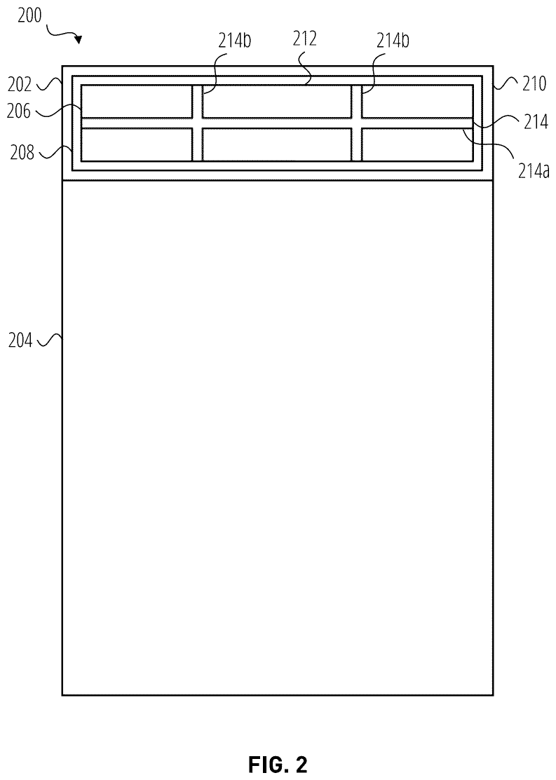

FIG. 2 illustrates a top view block diagram of a radiation detector 200. The radiation detector 200 can be the same as or similar to the radiation detector 100, except that the radiation detector 200 includes a housing 202 disposed to the side of an imaging array 204. The imaging array 204 can be a flexible imaging array, which can be wrapped around an object to be imaged. As an example, the imaging array 204 can be used in an industrial imaging context in which the imaging array 204 is wrapped around a pipe and used to image the pipe. However, the radiation detector 200 can be used in any suitable applications.

As illustrated in FIG. 2, the radiation detector 200 includes an electronics board 206 and a baseplate 208 disposed in the housing 202. The housing 202 and a cover 210 can define an enclosure in which the electronics board 206 and the baseplate 208 can be positioned. The electronics board 206 and the baseplate 208 can be coupled to one another, the housing 202, and/or the cover 210. The electronics board 206 can be electrically coupled to the imaging array 204 through the housing 202. The imaging array 204 can be coupled to the housing 202. As illustrated in FIG. 2, the housing 202, the electronics board 206, the baseplate 208, and the cover 210 can overlap one another, and the imaging array 204 can be disposed to the side of the housing 202, the electronics board 206, the baseplate 208, and the cover 210. Specifically, the electronics board 206 can be disposed outside of a periphery of the imaging array 204.

As illustrated in FIG. 2, the electronics board 206 can include rigid portions 212 and flexible portions 214. Active components or circuits of the electronics board 206 can be disposed on, in, or coupled to the rigid portions 212 and the flexible portions 214 can include electrical connections between the active components (and between the rigid portions 212). The flexible portions 214 can include a single horizontal flex 214a (extending in a direction parallel to a longitudinal axis of the electronics board 206) and two vertical flexes 214b (extending in a direction perpendicular to the longitudinal axis of the electronics board 206). The number and arrangement of the horizontal flexes 214a and the vertical flexes 214b can provide the electronics board 206 with varying degrees of flexibility in directions parallel to the horizontal flexes 214a and the vertical flexes 214b. Providing a greater number of flexible portions 214 or providing the flexible portions 214 with greater widths can provide the electronics board 206 with greater levels of flexibility in directions parallel to the respective flexible portions 214. Providing greater areas of the flexible portions 214 can leave less space for active components in the rigid portions 212, and the arrangement of the flexible portions 214 and the rigid portions 212 can be optimized for applications of the radiation detector 200.

As discussed above with respect to the radiation detector 100 of FIGS. 1A and 1B, the housing 202, the electronics board 206, and the cover 210 can be formed from flexible materials. The baseplate 208 can be provided to provide a desired amount of stiffness or rigidity to the housing 202, while maintaining a low weight. By forming components of the radiation detector 200 from flexible materials, the radiation detector 200 can have an increased durability and longevity. Moreover, conventional components that are used to stiffen and add rigidity to the radiation detector 200 can be omitted, which can reduce the cost and weight of the radiation detector 200. The baseplate 208 can be included to still provide a desired level of rigidity and flexibility to the radiation detector 200, while minimizing weight. By forming the electronics board 206 and the cover 210 from flexible materials, failures in the radiation detector 200 caused by damage to a cover glass, an electronics board, and a connection between the cover glass and the electronics board (e.g., three of the top causes of failure for the radiation detector 200) can be reduced or eliminated. This can significantly reduce failures in the radiation detector 200. Forming the housing 202, the electronics board 206, and the cover 210 from flexible materials can further aid in positioning the radiation detector 200 relative to an object to be imaged, such as in a case where the radiation detector 200 (e.g., the imaging array 204) is wrapped around a pipe.

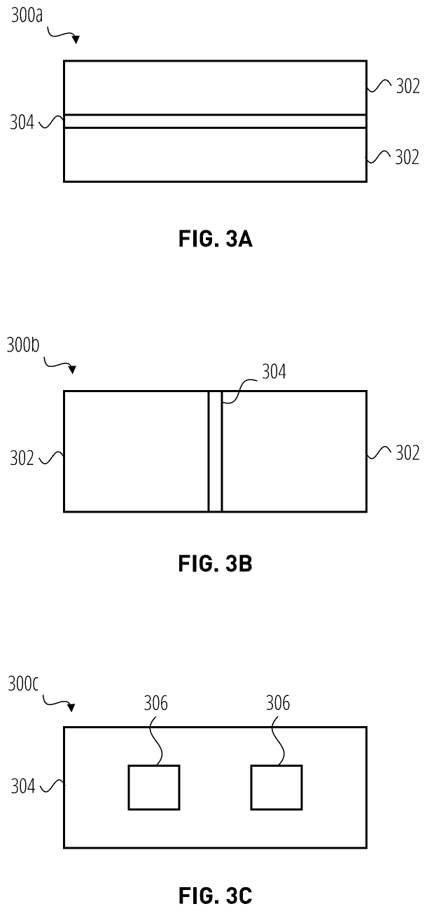

FIGS. 3A through 3C illustrate examples of electronics boards that can be included in the detectors of the present application. For example, electronics boards 300a, 300b, 300c illustrated in FIGS. 3A through 3C can be used as the electronics board 104 in the radiation detector 100 of FIGS. 1A and 1B, as the electronics board 206 in the radiation detector 200 of FIG. 2, or as an electronics board in any other radiation detector. FIGS. 3A through 3C illustrate various configurations of rigid portions, flexible portions, and active components that can be included in electronics boards, which can be included in radiation detectors.

FIG. 3A illustrates an example in which an electronics board 300a includes a single flex portion 304 that extends in a horizontal direction. As illustrated in FIG. 3A, the horizontal direction can be parallel to a longitudinal axis of the electronics board 300a. The electronics board 300a can include two rigid portions 302 with the flex portion 304 extending between the two rigid portions 302. The flex portion 304 can electrically couple active components on the rigid portions 302 and can provide electrical communication between the rigid portions 302.

Although FIG. 3A illustrates a single horizontal flex portion 304 and two rigid portions 302, the electronics board 300a can include any number of horizontal flex portions 304 and any number of rigid portions 302. Providing a greater number of the flex portions 304 can provide the electronics board 300a with an increased level of flexibility. The number and positioning of the flex portions 304 and the rigid portions 302 included in the electronics board 300a can depend on characteristics of a radiation detector on which the electronics board 300a is to be mounted. For example, detectors with higher performance can use larger areas of the rigid portions 302, while detectors with higher flexibility requirements can use a greater number of the flex portions 304.

FIG. 3B illustrates an example in which an electronics board 300b includes a single flex portion 304 that extends in a vertical direction. As illustrated in FIG. 3B, the vertical direction can be perpendicular to a longitudinal axis of the electronics board 300b. The electronics board 300b can include two rigid portions 302 with the flex portion 304 extending between the two rigid portions 302. The flex portion 304 can electrically couple active components on the rigid portions 302 and can provide electrical communication between the rigid portions 302.

Although FIG. 3B illustrates a single vertical flex portion 304 and two rigid portions 302, the electronics board 300b can include any number of vertical flex portions 304 and any number of rigid portions 302. Providing a greater number of the flex portions 304 can provide the electronics board 300b with an increased level of flexibility. The number and positioning of the flex portions 304 and the rigid portions 302 included in the electronics board 300b can depend on characteristics of a radiation detector on which the electronics board 300b is to be mounted. For example, detectors with higher performance can use larger areas of the rigid portions 302, while detectors with higher flexibility requirements can use a greater number of the flex portions 304. Further, electronics boards can include any number of the horizontal flex portions 304 discussed in reference to the electronics board 300a of FIG. 3A and any number of the vertical flex portions 304 discussed in reference to the electronics board 300b of FIG. 3B.

FIG. 3C illustrates an example in which an electronics board 300c includes a flex portion 304 and active components 306 coupled to the flex portion 304. In the example of FIG. 3C, the flex portion 304 can define a majority of the area of the electronics board 300c (e.g., greater than about 50%, greater than about 60%, greater than about 70%, greater than about 80%, greater than about 90%, or the like). In some examples, areas in which the active components 306 are coupled to the flex portion 304 can be stiffened or can be rigid. For example, a rigid layer (e.g., an FR-4 glass epoxy, another glass-reinforced epoxy laminate material, or the like) can be applied to or coupled to the flex portion 304 in areas where the active components 306 will be coupled. The active components 306 can be coupled to the rigid layer or to the flex portion 304 opposite the rigid layer. In some examples, the active components 306 can be coupled to the flex portion 304 through a bonding technique with improved adhesion, such as edge bonding, corner bonding, or the like. In the example of FIG. 3C, a majority of the electronics board 300c can be flexible, with selected areas of the electronics board 300c being rigid (e.g., locations in which the active components 306 are disposed). This can maximize the flexibility of the electronics board 300c. Although FIG. 3C illustrates an electronics board 300c that includes two active components 306 coupled to the flex portion 304, any number of active components 306 can be coupled to the flex portion 304 in any desired positions. The flex portion 304 can be provided to electrically couple the active components 306 to one another and can provide electrical communication between the active components 306.

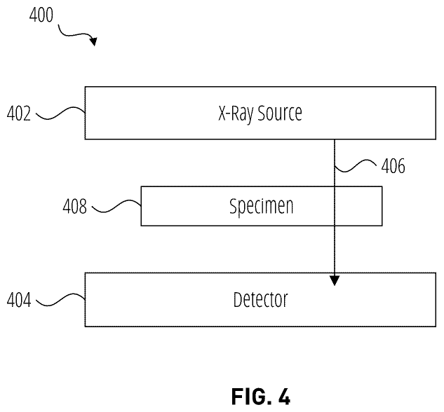

FIG. 4 is a block diagram of an x-ray imaging system 400. The x-ray imaging system 400 includes an x-ray source 402 and a detector 404. The detector 404 can include a flexible detector, such as either of the detectors 100, 200, discussed above with respect to FIGS. 1A through 2. The x-ray source 402 is positioned relative to the detector 404 such that x-rays 406 generated by the x-ray source 402 can be directed to pass through a specimen 408 and attenuated x-rays can be detected by the detector 404. The detector 404 can be used as part of an x-ray imaging system 400 for medical imaging, diagnostics, radiotherapy, non-destructive testing, materials detection or analysis, security inspection, or the like. The x-ray imaging system 400 can be any system that includes a radiation detector, such as an x-ray detector.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A radiation detector comprising:
a flexible housing;
an electronics board positioned in the flexible housing, the electronics board comprising at least two rigid portions and a flexible portion coupled to the rigid portions, each of the rigid portions comprising active components; and
a sensor array at least partially overlapping the electronics board.

2. The radiation detector of claim 1, further comprising a flexible cover.

3. The radiation detector of claim 2, wherein the flexible cover comprises a polymer.

4. The radiation detector of claim 1, further comprising a baseplate, the baseplate comprising one or more materials selected from carbon fiber, plastic materials, metal materials, fiberglass, or an epoxy resin.

5. The radiation detector of claim 4, wherein the baseplate is configured to provide the flexible housing with a desired level of stiffness.

6. The radiation detector of claim 1, wherein the flexible housing comprises a plastic material.

7. The radiation detector of claim 1, further comprising a second flexible portion, wherein:
the first flexible portion extends in a first direction; and
the second flexible portion extends in a second direction perpendicular to the first portion.

8. The radiation detector of claim 1, wherein the flexible portion is defined by a flexible layer extending between the at least two rigid portions.

9. A radiation detector comprising:
a first integrated circuit;
a second integrated circuit coupled to the first integrated circuit by a flexible connection;
a housing enclosing the first integrated circuit, the second integrated circuit, and the flexible connection; and
a sensor array coupled to the first integrated circuit.

10. The radiation detector of claim 9, wherein the sensor array is disposed within the housing.

11. The radiation detector of claim 9, wherein the sensor array at least partially overlaps at least one of the first integrated circuit, the second integrated circuit, or the flexible connection.

12. The radiation detector of claim 9, wherein the sensor array is disposed outside of the housing.

13. The radiation detector of claim 9, wherein:
the first integrated circuit is formed on a first rigid portion of an electronics board;
the second integrated circuit is formed on a second rigid portion of the electronics board; and
the flexible connection is a flexible portion of the electronics board extending between the first rigid portion and the second rigid portion.

14. The radiation detector of claim 9, further comprising a cover coupled to the housing, the cover and the housing defining an enclosure in which the first integrated circuit and the second integrated circuit are disposed.

15. The radiation detector of claim 14, wherein the cover comprises polyethylene terephthalate or polyimide.

16. An imaging system comprising:
an x-ray source; and
an x-ray detector comprising:
an electronics housing comprising:
an electronics board, the electronics board comprising a flex between two rigid portions, the rigid portions comprising active components; and
a sensor array coupled to the electronics housing, the sensor array comprising a plurality of sensors disposed outside of a periphery of the electronics housing.

17. The imaging system of claim 16, wherein:
the flex is a first flex extending in a first direction;
the electronics board further comprises a second flex; and
the second flex extends in a second direction parallel to the first direction.

18. The imaging system of claim 16, wherein:
the flex is a first flex extending in a first direction;
the electronics board further comprises a second flex; and
the second flex extends in a second direction perpendicular to the first direction.

19. The imaging system of claim 16, wherein:
the electronics housing comprises a flexible cover coupled to a flexible housing portion; and
the flexible housing portion defines a back surface and sidewalls of the electronics housing.

20. The imaging system of claim 16, wherein the sensor array is a flexible sensor array configured to be wrapped around an object to be imaged.
